(19) United States
(12) Patent Application Publication
(10) Pub. No.: US 2025/0118390 A1
(43) Pub. Date: Apr. 10, 2025

(54) TEST DEVICE, OPERATING METHOD OF THE SAME, AND TEST SYSTEM

(71) Applicant: Samsung Electronics Co., Ltd., Suwon-si (KR)

(72) Inventors: Sunggu Lee, Suwon-si (KR); Kwangkyu Kim, Suwon-si (KR)

(21) Appl. No.: 18/904,629

(22) Filed: Oct. 2, 2024

(30) Foreign Application Priority Data
Oct. 6, 2023 (KR) 10-2023-0133691

(51) Int. Cl. G11C 29/56

(52) U.S. Cl. CPC G11C 29/56016; G11C 29/56008; G11C 2029/5602

(57) ABSTRACT

A test device includes a vector memory configured to store a plurality of vector data, a test control circuit configured to test an external memory device by receiving a first vector data, transmitting a memory request, a memory address, and memory data included in the first vector data, and comparing read data from the external memory device with expected data, and a physical layer configured to communicate with the external memory device through data lines and a command/address line, output a command corresponding to the memory request and an address corresponding to the memory address through the command/address line, output write data corresponding to the memory data through the data lines, receive the memory request, the memory address, and the memory data from the test control circuit, and receive the read data from the external memory device through the data lines.

### CROSS-REFERENCE TO RELATED APPLICATION(S)

This application is based on and claims priority under 35 U.S.C. § 119 to Korean Patent Application No. 10-2023-0133691, filed on Oct. 6, 2023 in the Korean Intellectual Property Office, the disclosure of which is incorporated by reference herein in its entirety.

### BACKGROUND

The inventive concept relates to a semiconductor memory, and more particularly, to a test device, an operating method of the same, and a test system including the test device.

Semiconductor memories are classified into volatile memory devices, which lose data stored therein at power-off, such as static random-access memory (SRAM) and dynamic RAM (DRAM), and non-volatile memory devices, which retain data stored therein even at power-off, such as a flash memory device, phase-change RAM (PRAM), magnetic RAM (MRAM), resistive RAM (RRAM), and ferroelectric RAM (FRAM).

Semiconductor memory devices are devices that store data. Recently, as electronic devices and semiconductor memory devices have become smaller and more highly integrated, the design of semiconductor memory devices has become more diverse, and a process of testing the functionality of a designed or manufactured semiconductor memory device has become more complex.

For example, it takes substantial time and effort to develop a memory test device and set new conditions for each semiconductor memory device, considering the type of a memory device to be tested, a standard specification applied to the memory device, the content of a test operation to be performed on the memory device, the range of memory cells for performing the test operation among memory cells of the memory device, and a protocol used for communication with the memory device.

### SUMMARY

The inventive concept provides a test device that is easy to manufacture and develop and has a wide test coverage, an operating method of the test device, and a test system.

According to an aspect of the inventive concept, there is provided a test device including a vector memory configured to store a plurality of vector data, a test control circuit configured to test an external memory device by receiving a first vector data among the plurality of vector data, transmitting a memory request, a memory address, and memory data included in the first vector data, and comparing read data from the external memory device with expected data, and a physical layer configured to communicate with the external memory device through data lines and a command/address line, output a command corresponding to the memory request and an address corresponding to the memory address through the command/address line, output write data corresponding to the memory data through the data lines, receive the memory request, the memory address, and the memory data from the test control circuit, and receive the read data from the external memory device through the data lines, wherein the first vector data includes the memory request, the memory address, the memory data, and the expected data.

According to another aspect of the inventive concept, there is provided an operating method of a test device including a physical layer, a vector memory, and a test control circuit, the physical layer, the operating method including receiving, by the test control circuit, vector data stored in the vector memory, transmitting, by the test control circuit, a memory request, a memory address, and memory data included in the vector data to the physical layer, transmitting, by the physical layer, a command corresponding to the memory request and an address corresponding to the memory address, to an external memory device through a command/address line, and transmitting, by the physical layer, data corresponding to the memory data to the external memory device through data lines.

According to another aspect of the inventive concept, there is provided a test system including a test device and a memory device, wherein the test device includes a vector memory configured to store a plurality of vector data, a test control circuit configured to test the memory device by receiving a first vector data among the plurality of vector data, transmitting a memory request, a memory address, and memory data included in the first vector data, and comparing read data from the memory device with expected data included in the first vector data to generate and store a test result, and a physical layer configured to communicate with the memory device through data lines and a command/address line, output a command corresponding to the memory request and an address corresponding to the memory address, through the command/address line, and output write data corresponding to the memory data through the data lines, and receive the read data through the data lines. The physical layer includes an intellectual property (IP) block, and the memory request, the memory address, and the memory data are signals defined by a double data rate (DDR) PHY interface (DFI) standard.

### BRIEF DESCRIPTION OF THE DRAWINGS

Embodiments will be more clearly understood from the following detailed description taken in conjunction with the accompanying drawings in which:

FIG. 1 is a block diagram illustrating a test system according to an embodiment;

FIG. 2 is a block diagram illustrating vector data according to an embodiment;

FIG. 3 is a block diagram illustrating a test system according to an embodiment;

FIGS. 4A and 4B are each a block diagram illustrating an example of an operating method of a test system according to an embodiment;

FIG. 5 is a block diagram illustrating a test system according to an embodiment;

FIG. 6 is a block diagram illustrating an example of an operating method of a test system according to an embodiment;

FIG. 7 is a block diagram illustrating a test system according to an embodiment;

FIG. 8 is a flowchart illustrating an example of an operating method of a command decoder according to an embodiment;

FIG. 9 is a block diagram illustrating a test system according to an embodiment;

FIG. 10 is a flowchart illustrating an example of an operating method of a test system according to an embodiment;

FIG. 11 is a block diagram illustrating a memory device according to an embodiment;

FIGS. 12A and 12B are each a timing diagram illustrating an operation of a test device according to an embodiment;

FIG. 13 is a flowchart illustrating an example of an operating method of a test system according to an embodiment;

FIG. 14 is a flowchart illustrating an example of an operating method of a test system according to an embodiment; and

FIG. 15 is a block diagram illustrating a test system according to an embodiment.

### DETAILED DESCRIPTION OF THE EMBODIMENTS

Hereinafter, embodiments will be described in detail and clearly to such an extent that one of ordinary skill in the art may easily implement the inventive concept.

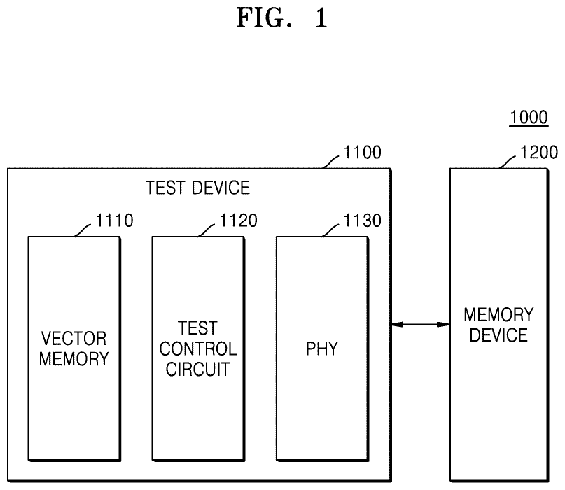

FIG. 1 is a block diagram illustrating a test system 1000 according to an embodiment.

Referring to FIG. 1, the test system 1000 may include a test device 1100 and a memory device 1200. In an embodiment, the test system 1000 may be used to detect defects in the memory device 1200 during a manufacturing process of the memory device 1200. That is, the test system 1000 may test defects in the memory device 1200 in advance.

The test device 1100 may include a vector memory 1110, a test control circuit 1120, and a physical layer (PHY) 1130. The test device 1100 may perform a test operation on the memory device 1200. The test device 1100 may perform a test operation to detect defects in the memory device 1200. For example, the test device 1100 may perform a test operation to determine whether or not the memory device 1200 normally performs various operations (e.g., a write operation, a read operation, a mode setting operation, etc.).

The test device 1100 may be configured to control the memory device 1200 in order to test an operation of the memory device 1200. The test device 1100 may write test data to the memory device 1200 based on vector data (or a packet) stored in the vector memory 1110. The test device 1100 may read the test data written in the memory device 1200. The test device 1100 may determine whether or not the memory device 1200 is defective by comparing the read test data with original data (or expected data). That is, the test system 1000 may determine whether or not the memory device 1200 has a defect, based on the test data and the expected data.

The test device 1100 may transmit a command or data to the memory device 1200. The test device 1100 may receive data from the memory device 1200. For example, the test device 1100 may transmit a test command and test write data to the memory device 1200. The test device 1100 may receive test read data from the memory device 1200.

The vector memory 1110 may store test data. The test data may include a plurality of vector data. The vector memory 1110 may store the plurality of vector data. For example, the vector data may include a memory request, a memory address, memory data, and expected data.

The vector memory 1110 may output the vector data in response to a load command received from the test control circuit 1120. The vector memory 1110 may transmit the vector data stored therein to the test control circuit 1120. For example, the vector memory 1110 may be at least one of various types of memories, such as static random-access memory (SRAM), dynamic RAM (DRAM), resistive RAM (RRAM), ferroelectric RAM (FRAM), phase-change RAM (PRAM), magnetic RAM (MRAM), and flash memory.

The test control circuit 1120 may test the memory device 1200 through the PHY 1130. The test control circuit 1120 may control the memory device 1200 through the PHY 1130. In an embodiment, the test control circuit 1120 and the PHY 1130 may communicate with each other according to the double data rate (DDR) PHY interface (DFI) communication protocol.

The test control circuit 1120 may receive the vector data from the vector memory 1110. The test control circuit 1120 may transmit the memory request, the memory address, and the memory data in the vector data to the PHY 1130. The test control circuit 1120 may compare the expected data included in the vector data with read data. For example, the read data may refer to data received from the memory device 1200 through the PHY 1130. The test control circuit 1120 may test the memory device 1200 by comparing the read data with the expected data to generate and store a test result.

The PHY 1130 may communicate with the memory device 1200. The PHY 1130 may communicate with the memory device 1200 through a command/address line, data lines, a data strobe line, etc. The PHY 1130 may output a command corresponding to the memory request and an address corresponding to the memory address through the command/address line. The PHY 1130 may output write data corresponding to the memory data through the data lines. The PHY 1130 may receive the read data through the data lines. For example, the memory request, the memory address, and the memory data may be signals defined by the DFI standard. The memory request, the memory address, and the memory data may have a DFI format.

In an embodiment, the PHY 1130 may be electrically connected to the memory device 1200. The PHY 1130 may be electrically connected to a physical layer of the memory device 1200. The PHY 1130 may also be referred to as a memory interface circuit.

In an embodiment, the PHY 1130 may be an intellectual property (IP) block. The PHY 1130 may be a DDR PHY IP block. Designers of integrated circuits, such as a system-on-chip (SoC), a microprocessor, a micro-controller, and other systems, may use IP blocks to simplify system design. IP blocks are modular, self-contained hardware blocks that may be easily integrated into design. Because IP blocks are modular and self-contained, designers of integrated circuits may simply drop-in an IP block to use functions thereof. IP blocks may be ‘black boxes.’ That is, a system integrator using an IP block may not know or need to know specific implementation details of the IP block.

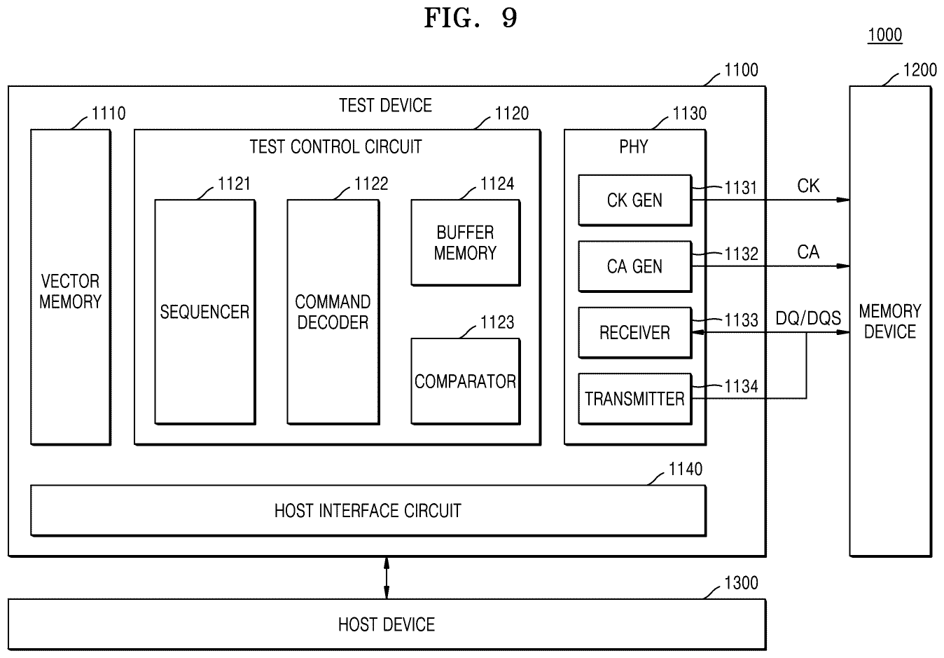

The memory device 1200 may operate under control by the test device 1100. For example, the memory device 1200 may be a device under test (DUT). For example, the memory device 1200 may receive a clock signal CK (see FIG. 9) and a command/address signal CA (see FIG. 9) from the test device 1100 and, in response to the received signals, may transmit a data signal DQ and a data strobe signal DQS to the test device 1100 (see FIG. 9) or receive the data signal DQ and the data strobe signal DQS from the test device 1100.

For example, the memory device 1200 may be a DRAM device, but the scope of the inventive concept is not limited thereto. For example, the memory device 1200 may include at least one of various types of memory devices, such as a DRAM device, an SRAM device, an RRAM device, an FRAM device, a PRAM device, an MRAM device, and a flash memory device.

Automatic test equipment (ATE) may include a timing generator and a pin control circuit. The timing generator and the pin control circuit may be implemented as application-specific integrated circuits (ASICs). The timing generator may generate a timing change in a test signal applied to a DUT or memory device. The pin control circuit may generate a level change (or a voltage change) in a test signal applied to a DUT or memory device. Due to the increase in speed or performance of memory devices, the difficulty of ATE development has increased, and the ATE development time has increased.

A test device including a memory controller may test a memory device by using only limited commands (e.g., read commands or write commands). The test device including the memory controller may have difficulty in transmitting commands on a clock cycle (or a clock period) basis. For example, the test device including the memory controller may have difficulty in transmitting an activate command, a write command, and a precharge command to a memory device at a timing desired by a user. The test device including the memory controller may have difficulty in performing various tests. The test device including the memory controller may have a test coverage lower than that of an ATE device.

The test device 1100 may detect defects occurring in the memory device 1200 by performing a test operation. The test device 1100 may include the PHY 1130, which is an IP block. The test device 1100 may include the PHY 1130, which is an IP block, instead of the timing generator and the pin control circuit of the ATE. In developing the test device 1100 including the PHY 1130, which is an IP block, development difficulty may be reduced, and development time and manufacturing costs may be reduced.

The test device 1100 may include the test control circuit 1120 instead of a memory controller. The test control circuit 1120 may perform a test operation on the memory device 1200 based on vector data. The test control circuit 1120 may transmit DFI signals included in the vector data to the PHY 1130 without changes. Accordingly, the test control circuit 1120 may not perform packet format conversion or data conversion. The test control circuit 1120 may be simplified or lightened. The test device 1100 may have an increased degree of freedom in test implementation. The test device 1100 may have a test coverage that is the same as or similar to that of the ATE.

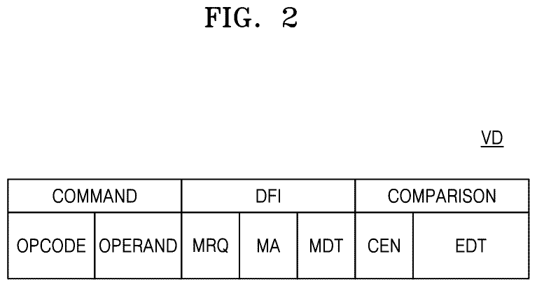

FIG. 2 is a block diagram illustrating vector data VD according to an embodiment.

Referring to FIGS. 1 and 2, the vector memory 1110 may store the vector data VD. The test control circuit 1120 may load the vector data VD from the vector memory 1110. In an embodiment, the vector data VD may include a command field, a DFI field, and a comparison field. The command field may include an operation code OPCODE and an operand OPERAND. The DFI field may include a memory request MRQ, a memory address MA, and memory data MDT. The comparison field may include a comparison enable signal CEN and expected data EDT. That is, the vector data VD may include the operation code OPCODE, the operand OPERAND, the memory request MRQ, the memory address MA, the memory data MDT, the comparison enable signal CEN, and the expected data EDT.

The command field may be used in the test control circuit 1120. The test control circuit 1120 may perform a decoding operation based on the command field. The operation code OPCODE may indicate one of a halt code and a loop code. When the operation code OPCODE indicates a halt code, the test control circuit 1120 may halt a test operation. The operand OPERAND may be used in setting a loop counter. For example, the operand OPERAND may be used to adjust a time interval between commands transmitted to the memory device 1200.

The DFI field may be input to the PHY 1130. The memory request MRQ may correspond to a command transmitted to the memory device 1200, the memory address MA may correspond to an address transmitted to the memory device 1200, and the memory data MDT may correspond to data transmitted to the memory device 1200. The data transmitted to the memory device 1200 may include a data signal DQ and a data strobe signal DQS.

In an embodiment, the DFI field may include signals input to the PHY 1130 according to the DFI standard. For example, the DFI field may include a DFI address bus signal, a DFI bank bus signal, a DFI column address strobe signal, a write data bus signal, a write data and data mask signal, a read data bus signal, a read data enable signal, etc. However, the scope of the inventive concept is not limited thereto.

The comparison field may be used in the test control circuit 1120. The comparison enable signal CEN may be a signal for enabling a comparator of the test control circuit 1120. When the comparison enable signal CEN is enabled, the test control circuit 1120 may compare the expected data EDT with read data. The expected data EDT may be test data written in the memory device 1200. The expected data EDT may be used in comparing with read data received from the memory device 1200.

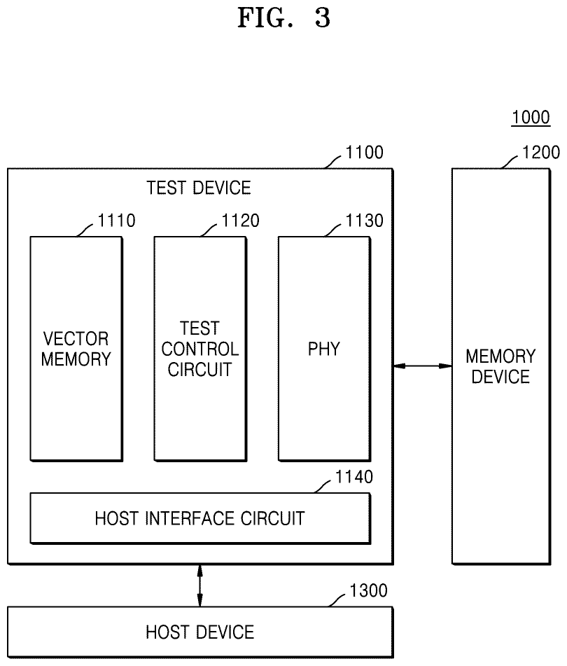

FIG. 3 is a block diagram illustrating the test system 1000 according to an embodiment.

Referring to FIGS. 1 and 3, the test system 1000 may include the test device 1100, the memory device 1200, and a host device 1300. The test device 1100 may include the vector memory 1110, the test control circuit 1120, the PHY 1130, and a host interface circuit 1140. For convenience of description, detailed description of the components described above is omitted.

The host device 1300 may test the memory device 1200 through the test device 1100. For example, the host device 1300 may be one of various computing devices, such as a desktop computer, a laptop computer, a workstation, a server, a smartphone, a tablet personal computer (PC), a digital camera, and a black box.

The host device 1300 may control an operation of the test device 1100. The host device 1300 may execute an operating system, a program, or an application. For example, the host device 1300 may include a user interface (not shown). The host device 1300 may receive test parameters from a user through the user interface. Alternatively, the host device 1300 may receive setup information through the user interface.

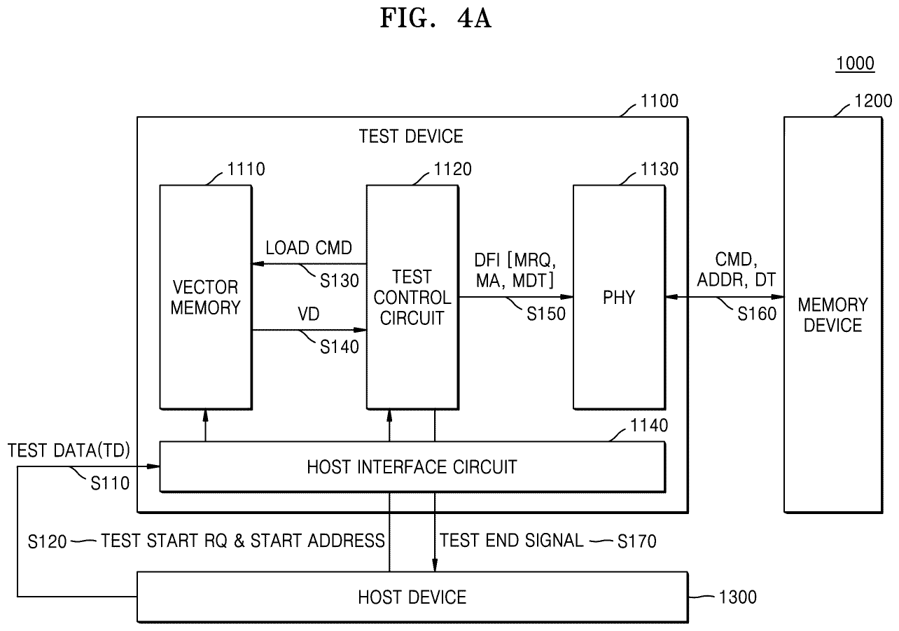

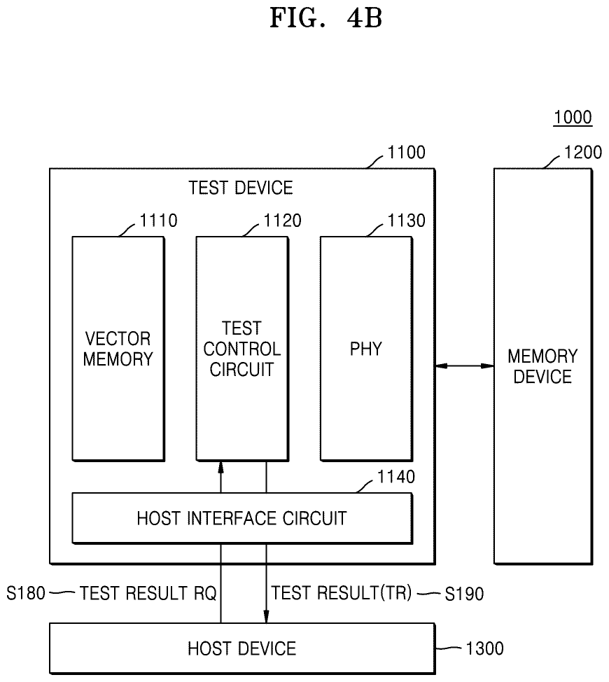

In an embodiment, the host device 1300 may generate test data TD (see FIG. 4A) based on the test parameters. The test parameters may include the type of the memory device 1200, a standard specification applied to the memory device 1200, a protocol used for communication with the memory device 1200, the type of a test operation to be performed on the memory device 1200, the range of memory addresses for performing the test operation, etc. The host device 1300 may generate a plurality of vector data VD based on the test parameters. The host device 1300 may transmit the test data TD including the plurality of vector data VD to the test device 1100. The host device 1300 may store the test data TD (or the plurality of vector data VD) in the vector memory 1110 of the test device 1100.

The host device 1300 may transmit a test start request and a start address to the test device 1100. The test start request may be a request for the test device 1100 to start a test operation on the memory device 1200. The start address may indicate an address of the vector data VD to be first loaded by the test device 1100.

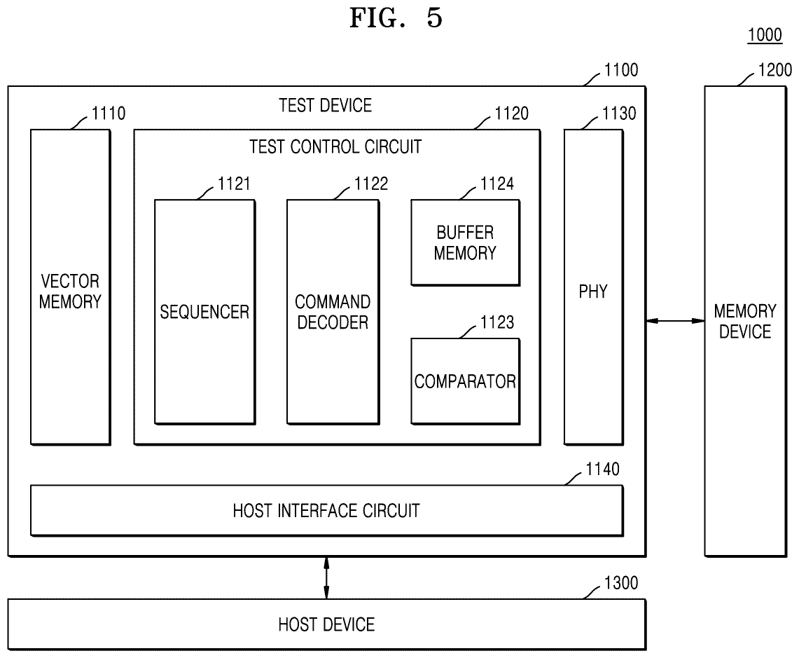

The host device 1300 may receive a test end signal from the test device 1100. The host device 1300 may read a test result stored in a buffer memory 1124 (see FIG. 5), in response to the test end signal. The host device 1300 may transmit a test result request to the test device 1100 in response to the test end signal.

For example, the test result request may be used to request the test result stored in the buffer memory 1124. The test result may include a plurality of fail entries. A fail entry may include a fail address, read data, or expected data. The host device 1300 may receive the test result from the test device 1100. The host device 1300 may detect a defect in the memory device 1200 based on the test result.

The test device 1100 may communicate with the host device 1300 through the host interface circuit 1140. The test device 1100 may receive the test data TD (or the plurality of vector data VD) from the host device 1300. The test device 1100 may store the test data TD in the vector memory 1110. The test device 1100 may receive the test start request or start address from the host device 1300.

The test device 1100 may transmit the test end signal to the host device 1300. The test device 1100 may receive the test result request. The test device 1100 may transmit the test result stored in the buffer memory 1124 to the host device 1300, in response to the test result request.

FIGS. 4A and 4B are each a block diagram illustrating an example of an operating method of the test system 1000 according to an embodiment.

Referring to FIGS. 3 and 4A, in operation S110, the host device 1300 may transmit the test data TD to the test device 1100. The host device 1300 may generate the test data TD to test the memory device 1200. The test data TD may include a plurality of vector data VD. The host device 1300 may store the test data TD in the vector memory 1110 of the test device 1100. The test device 1100 may receive the test data TD through the host interface circuit 1140. The test device 1100 may store the test data TD in the vector memory 1110.

In operation S120, a test start request and a start address may be transmitted to the test device 1100. The host device 1300 may transmit the test start request and the start address to the test device 1100 to start a test operation on the memory device 1200. The test device 1100 may receive the test start request and the start address through the host interface circuit 1140. The test control circuit 1120 may receive the test start request and the start address.

In operation S130, the test control circuit 1120 may transmit a load command to the vector memory 1110. The test control circuit 1120 may transmit the load command to the vector memory 1110 in response to the test start request. The load command may include the start address. The test control circuit 1120 may read the vector data VD corresponding to the start address. The test control circuit 1120 may read the vector data VD while sequentially increasing addresses from the start address.

In operation S140, the vector memory 1110 may transmit the vector data VD to the test control circuit 1120. The vector memory 1110 may transmit the vector data VD corresponding to the start address to the test control circuit 1120, in response to the load command. The test control circuit 1120 may receive the vector data VD.

In operation S150, the test control circuit 1120 may transmit the DFI field in the vector data VD to the PHY 1130. The test control circuit 1120 may perform a decoding operation based on the vector data VD. The test control circuit 1120 may determine whether or not to continue performing a test based on the operation code OPCODE included in the vector data VD.

The test control circuit 1120 may extract the DFI field from the vector data VD. The test control circuit 1120 may transmit the memory request MRQ, the memory address MA, and the memory data MDT in the vector data VD to the PHY 1130. The test control circuit 1120 may transmit the DFI standard signals included in the vector data VD to the PHY 1130 without changes.

The PHY 1130 may receive the DFI field in the vector data VD. The PHY 1130 may receive the memory request MRQ, the memory address MA, and the memory data MDT. The PHY 1130 may receive the DFI standard signals included in the vector data VD without changes.

In operation S160, the PHY 1130 may transmit a command CMD, an address ADDR, and data DT to the memory device 1200. The data DT may include a data signal DQ and a data strobe signal DQS. The PHY 1130 may transmit the command CMD, the address ADDR, and the data

DT based on the DFI field received from the test control circuit 1120. In an embodiment, the command CMD and the address ADDR may be transmitted through a command/address line, the data signal DQ may be transmitted through a data line, and the data strobe signal DQS may be transmitted through a data strobe line. The command CMD may correspond to the memory request MRQ, the address ADDR may correspond to the memory address MA, and the data DT may correspond to the memory data MDT.

The test device 1100 may repeatedly perform operations S130 to S160. The test device 1100 may repeatedly perform operations S130 to S160 until the test operation is halted.

In operation S170, the test device 1100 may transmit a test end signal to the host device 1300. For example, the test end signal may be a signal for notifying the host device 1300 that the test operation has been completed. When the test control circuit 1120 determines that the operation code OPCODE in the vector data VD indicates a halt code, the test control circuit 1120 may halt the test operation. The test control circuit 1120 may transmit the test end signal to the host device 1300 through the host interface circuit 1140, in response to the operation code OPCODE, which is a halt code. In an embodiment, the test end signal may indicate whether or not the test device 1100 detects a defect in the memory device 1200.

In operation S180, the host device 1300 may transmit a test result request to the test device 1100. For example, the host device 1300 may transmit a test result request command to the test device 1100. The test result request may be a request for a test result stored in the test device 1100. For example, the test result request may be a test result request command. The test result may be a log of defects (or errors) detected by testing the memory device 1200. For example, the test result may include a plurality of fail entries. Each of the plurality of fail entries may include a memory address, read data, and expected data. The test control circuit 1120 may receive the test result request (or test result request command) through the host interface circuit 1140. For example, the host device 1300 may transmit the test result request to the test control circuit 1120 after receiving the test end signal from the test control circuit 1120.

In operation S190, the test device 1100 may transmit a test result TR to the host device 1300. The test control circuit 1120 may transmit the test result TR stored in the test device 1100 to the host device 1300 through the host interface circuit 1140, in response to a test result request (or test result request command).

As described above, the vector data VD may include a DFI field (or DFI signals). The test control circuit 1120 may transmit the DFI signals included in the vector data VD without changes. The test control circuit 1120 may not newly generate a DFI signal or convert a DFI signal based on the vector data VD. Accordingly, the test control circuit 1120 may be simplified and lightened.

FIG. 5 is a block diagram illustrating the test system 1000 according to an embodiment.

Referring to FIG. 5, the test system 1000 may include the test device 1100, the memory device 1200, and the host device 1300. The test device 1100 may include the vector memory 1110, the test control circuit 1120, the PHY 1130, and the host interface circuit 1140. For convenience of description, detailed description of the components described above is omitted.

In an embodiment, the test control circuit 1120 may include a sequencer 1121, a command decoder 1122, a comparator 1123, and the buffer memory 1124. The sequencer 1121 may perform a loading operation. The loading operation may refer to an operation of loading the vector data VD from the vector memory 1110. The sequencer 1121 may read the vector data VD from the vector memory 1110. The sequencer 1121 may transmit the vector data VD to the command decoder 1122.

The sequencer 1121 may start a loading operation in response to a test start request or start address received from the host device 1300. For example, the sequencer 1121 may receive a test start request and a start address from the host device 1300. The sequencer 1121 may load the vector data VD from the vector memory 1110 in response to the test start request. The sequencer 1121 may load the vector data VD corresponding to the start address. The sequencer 1121 may read the vector data VD while sequentially increasing addresses from the start address. The sequencer 1121 may transmit a load command to the vector memory 1110. The sequencer 1121 may receive the vector data VD from the vector memory 1110.

In an embodiment, the sequencer 1121 may read the vector data VD while sequentially increasing addresses from the start address until receiving a halt signal. The sequencer 1121 may receive the halt signal from the command decoder 1122. The sequencer 1121 may halt reading the vector data VD from the vector memory 1110, in response to the halt signal. The sequencer 1121 may no longer load the vector data VD after receiving the halt signal. The sequencer 1121 may halt the loading operation in response to the halt signal.

The command decoder 1122 may receive the vector data VD from the sequencer 1121. The command decoder 1122 may extract the command field from the vector data VD. The command decoder 1122 may extract the operation code OPCODE and the operand OPERAND from the vector data. The command decoder 1122 may extract the DFI field from the vector data VD. The command decoder 1122 may extract the memory request MRQ, the memory address MA, and the memory data MDT from the vector data VD. The command decoder 1122 may extract the comparison field from the vector data VD. The command decoder 1122 may extract the comparison enable signal CEN and the expected data EDT from the vector data VD.

The command decoder 1122 may transmit the DFI field in the vector data VD to the PHY 1130. The command decoder 1122 may transmit the memory request MRQ, the memory address MA, and the memory data MDT in the vector data VD to the PHY 1130. The command decoder 1122 may transmit the comparison field in the vector data VD to the comparator 1123. The command decoder 1122 may transmit the comparison enable signal CEN and the expected data EDT in the vector data VD to the comparator 1123.

The command decoder 1122 may perform a decoding operation. The command decoder 1122 may control a test based on the operation code OPCODE. The command decoder 1122 may halt a test operation in response to the operation code OPCODE, which is a halt code. The command decoder 1122 may adjust a time interval (or the number of clock cycles) between commands transmitted to the memory device 1200, based on the operation code OPCODE, which is a loop code, and the operand OPERAND.

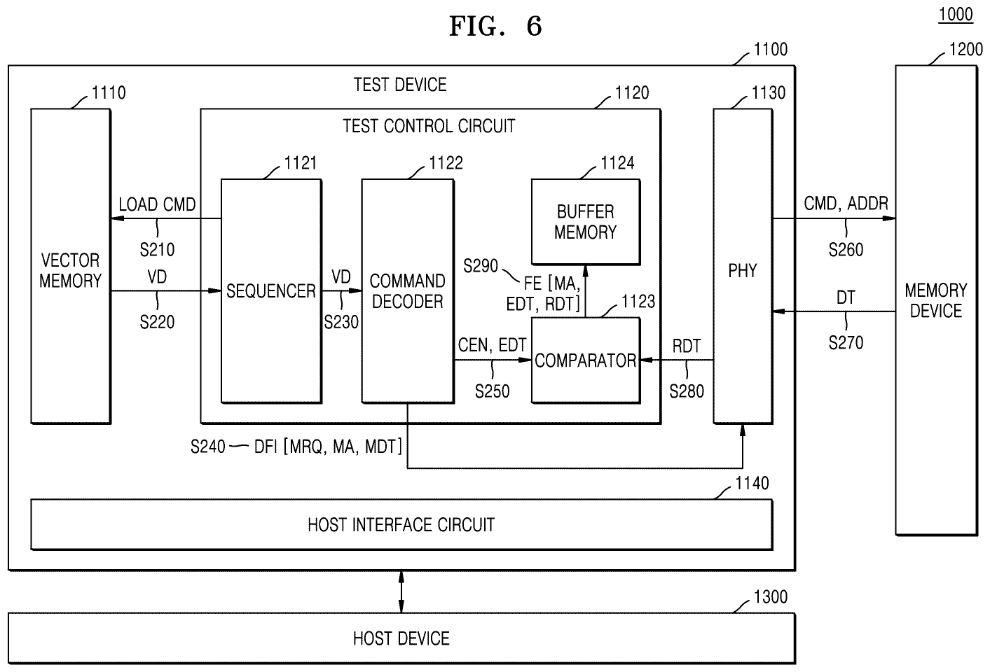

The comparator 1123 may receive the comparison enable signal CEN and the expected data EDT from the command decoder 1122. The comparator 1123 may receive read data RDT (see FIG. 6) from the PHY 1130. When the comparison enable signal CEN is enabled, the comparator 1123 may compare the read data RDT with the expected data EDT. The comparator 1123 may determine whether or not the read data RDT is the same as the expected data EDT.

When the read data RDT is different from the expected data EDT, the comparator 1123 may generate a fail entry FE (see FIG. 6). The fail entry FE may include the memory address MRA, the read data RDT, and the expected data EDT. The comparator 1123 may transmit the generated fail entry FE to the buffer memory 1124.

The buffer memory 1124 may receive the fail entry FE from the comparator 1123. The buffer memory 1124 may store the fail entry FE. The buffer memory 1124 may store a plurality of fail entries FE. The plurality of fail entries FE may be referred to as the test result TR. The buffer memory 1124 may store the test result TR.

The buffer memory 1124 may receive a test result request from the host device 1300 through the host interface circuit 1140. In response to the test result request, the buffer memory 1124 may transmit the test result TR (i.e., the plurality of fail entries FE) to the host device 1300 through the host interface circuit 1140.

FIG. 6 is a block diagram illustrating an example of an operating method of the test system 1000 according to an embodiment.

Referring to FIGS. 5 and 6, for convenience of description, detailed description of the operations described above is omitted. In operation S210, the sequencer 1121 may transmit a load command to the vector memory 1110. In operation S220, the vector memory 1110 may transmit the vector data VD corresponding to the load command to the sequencer 1121. In operation S230, the sequencer 1121 may transmit the vector data VD to the command decoder 1122.

In operation S240, the command decoder 1122 may transmit the DFI field to the PHY 1130. The command decoder 1122 may extract the DFI field from the vector data VD. The command decoder 1122 may extract the memory request MRQ, the memory address MA, and the memory data MDT from the vector data VD. The command decoder 1122 may transmit the memory request MRQ, the memory address MA, and the memory data MDT to the PHY 1130.

In operation S250, the command decoder 1122 may transmit the comparison field to the comparator 1123. The command decoder 1122 may extract the comparison enable signal CEN and the expected data EDT from the vector data VD. The command decoder 1122 may transmit the comparison enable signal CEN and the expected data EDT to the comparator 1123.

In operation S260, the PHY 1130 may transmit the command CMD and the address ADDR to the memory device 1200. For example, the PHY 1130 may transmit the command CMD and the address ADDR to the memory device 1200 through a command/address line. For example, the command CMD may be a read command. Accordingly, the PHY 1130 may not transmit data to the memory device 1200. The memory device 1200 may receive the command CMD and the address ADDR.

In operation S270, the memory device 1200 may transmit data DT to the PHY 1130. The data DT may be data corresponding to the command CMD. The PHY 1130 may receive the data DT. The data DT may include a data signal DQ and a data strobe signal DQS. In operation S280, the PHY 1130 may transmit the read data RDT to the comparator 1123. The PHY 1130 may transmit the read data RDT to the comparator 1123 based on the data DT. The PHY 1130 may transmit the data DT as the read data RDT to the comparator 1123. A value of the read data RDT may be the same as a value of the data DT. Alternatively, the read data RDT may be the data DT.

In operation S290, the comparator 1123 may transmit the fail entry FE to the buffer memory 1124. The comparator 1123 may receive the comparison enable signal CEN, the expected data EDT, and the read data RDT. When the comparison enable signal CEN is enabled, the comparator 1123 may compare the expected data EDT with the read data RDT. When the expected data EDT is different from the read data RDT, the comparator 1123 may generate the fail entry FE. The fail entry FE may include the memory address MA, the expected data EDT, and the read data RDT. The comparator 1123 may transmit the memory address MA, the expected data EDT, and the read data RDT to the buffer memory 1124. The buffer memory 1124 may receive the fail entry FE. The buffer memory 1124 may store the fail entry FE.

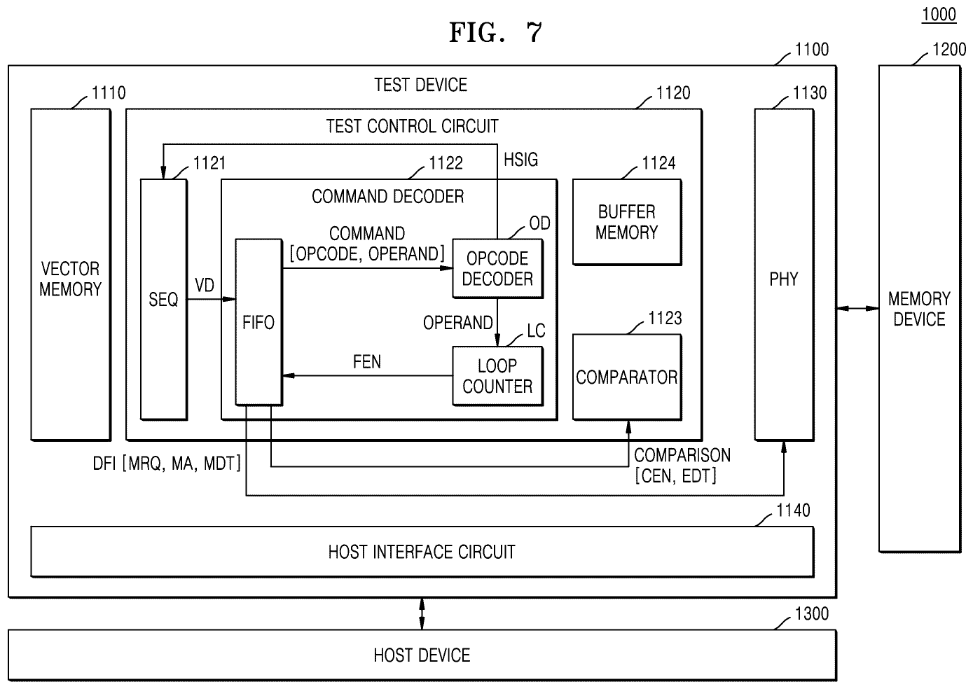

FIG. 7 is a block diagram illustrating the test system 1000 according to an embodiment.

Referring to FIG. 7, the test system 1000 may include the test device 1100, the memory device 1200, and the host device 1300. The test device 1100 may include the vector memory 1110, the test control circuit 1120, the PHY 1130, and the host interface circuit 1140. In an embodiment, the test control circuit 1120 may include the sequencer 1121, the command decoder 1122, the comparator 1123, and the buffer memory 1124. For convenience of description, detailed description of the components described above is omitted.

In an embodiment, the command decoder 1122 may include a first-in first-out (FIFO), an operation code decoder OD, and a loop counter LC. The FIFO may receive the vector data VD from the sequencer 1121. The FIFO may receive a FIFO enable signal FEN from the loop counter LC. The FIFO may output the vector data VD in response to the FIFO enable signal FEN.

The FIFO may output the vector data VD. The FIFO may transmit the command field in the vector data VD to the operation code decoder OD. The FIFO may transmit the operation code OPCODE and the operand OPERAND in the vector data VD to the operation code decoder OD. The FIFO may transmit the DFI field in the vector data VD to the PHY 1130. The FIFO may transmit the memory request MRQ, the memory address MA, and the memory data MDT in the vector data VD to the PHY 1130. The FIFO may transmit the comparison field in the vector data VD to the comparator 1123. The FIFO may transmit the comparison enable signal CEN and the expected data EDT in the vector data VD to the comparator 1123.

The operation code decoder OD may receive the command field from the FIFO. The operation code decoder OD may receive the operation code OPCODE and the operand OPERAND. The operation code decoder OD may perform a decoding operation based on the operation code OPCODE. When the operation code OPCODE indicates a halt code, the operation code decoder OD may output a halt signal HSIG to the sequencer 1121. When the operation code OPCODE indicates a loop code, the operation code decoder OD may transmit the operand OPERAND to the loop counter LC. In other words, the operation code decoder OD may output the halt signal HSIG to the sequencer 1121 in response to the operation code OPCODE indicating a halt code, and may transmit the operand OPERAND to the loop counter LC in response to the operation code OPCODE indicating a loop code.

The loop counter LC may receive the operand OPERAND from the operation code decoder OD. The loop counter LC may set the operand OPERAND as a count value. The loop counter LC may decrease the count value by 1 for each clock. When the count value is ‘0’, the loop counter LC may output the FIFO enable signal FEN to the FIFO. For example, the loop counter LC may output the FIFO enable signal FEN to the FIFO after the number of clock cycles corresponding to the count value. For example, if the count value is 5 the number of clock cycles is 5.

The sequencer 1121 may receive the halt signal HSIG from the operation code decoder OD. The sequencer 1121 may halt an operation. The sequencer 1121 may halt a loading operation of loading the vector data VD from the vector memory 1110. The sequencer 1121 may halt an operation of transmitting the vector data VD to the command decoder 1122. The sequencer 1121 may transmit a test end signal to the host device 1300 through the host interface circuit 1140 in response to the halt signal HSIG.

In an embodiment, the memory request MRQ included in the vector data VD may correspond to any one of an activate command, a precharge command, a write command, a read command, and a mode register set command. The test device 1100 may transmit a command to the memory device 1200 based on the vector data VD. Accordingly, the test device 1100 may transmit various commands other than the read command and the write command to the memory device 1200. The test device 1100 may test a plurality of commands defined in a standard specification.

As described above, the test control circuit 1120 may include the loop counter LC. By using the loop counter LC, the test control circuit 1120 may transmit commands to the memory device 1200 on a clock cycle basis. Accordingly, the test device 1100 may perform a test while adjusting a time interval between commands transmitted to the memory device 1200. The test device 1100 may have an increased test coverage.

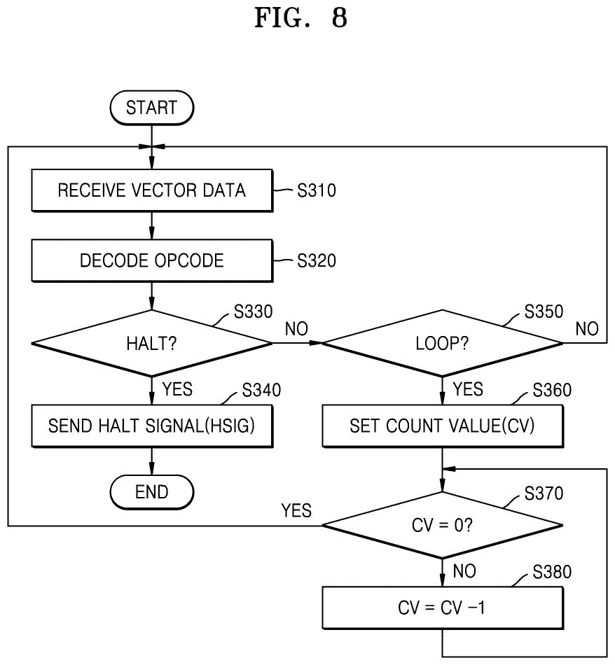

FIG. 8 is a flowchart illustrating an example of an operating method of the command decoder 1122 according to an embodiment.

Referring to FIGS. 7 and 8, in operation S310, the command decoder 1122 may receive the vector data VD. The FIFO may load the vector data VD from the sequencer 1121. In operation S320, the command decoder 1122 may decode the operation code OPCODE. The FIFO may transmit the command field to the operation code decoder OD. The operation code decoder OD may perform decoding based on the operation code OPCODE.

In operation S330, the command decoder 1122 may determine whether or not the operation code OPCODE is a halt code. When the operation code OPCODE is a halt code, the operation code decoder OD may perform operation S340. When the operation code OPCODE is not a halt code, the operation code decoder OD may perform operation S350.

In operation S340, the command decoder 1122 may transmit the halt signal HSIG to the sequencer 1121. The command decoder 1122 may output the halt signal HSIG to the sequencer 1121 to halt a test operation. The sequencer 1121 may receive the halt signal HSIG. The sequencer 1121 may halt a loading operation in response to the halt signal HSIG. The sequencer 1121 may halt an operation of transmitting the vector data VD to the command decoder 1122. The sequencer 1121 may transmit a test end signal to the host device 1300. For example, the sequencer 1121 may transmit the test end signal to the host device 1300 in response to the halt signal HSIG.

In operation S350, the command decoder 1122 may determine whether or not the operation code OPCODE is a loop code. When the operation code OPCODE is a loop code, the operation code decoder OD may perform operation S360. When the operation code OPCODE is not a loop code, the operation code decoder OD may perform operation S310.

In operation S360, the command decoder 1122 may set a count value CV. The operation code decoder OD may transmit the operand OPERAND to the loop counter LC. The loop counter LC may set the operand OERAND as the count value CV. The count value CV is used to describe repetition of loop operations and does not limit the scope of the inventive concept.

In operation S370, the command decoder 1122 may determine whether or not the count value CV is ‘0’. The command decoder 1122 may perform operation S310 when the count value CV is ‘0’, and may perform operation S380 when the count value CV is not ‘0’. In operation S380, the command decoder 1122 may decrease the count value CV by 1. Then, the command decoder 1122 may perform operation S370.

FIG. 9 is a block diagram illustrating the test system 1000 according to an embodiment.

Referring to FIG. 9, the test system 1000 may include the test device 1100, the memory device 1200, and the host device 1300. The test device 1100 may include the vector memory 1110, the test control circuit 1120, the PHY 1130, and the host interface circuit 1140. In an embodiment, the test control circuit 1120 may include the sequencer 1121, the command decoder 1122, the comparator 1123, and the buffer memory 1124. For convenience of description, detailed description of the components described above is omitted.

Under control by the test control circuit 1120, the PHY 1130 may transmit the clock signal CK and the command/address signal CA to the memory device 1200, and may exchange the data signal DQ and the data strobe signal DQS with the memory device 1200. For example, the PHY 1130 may be a DDR-PHY configured to support a DDR interface. For example, the PHY 1130 may be configured to support various standard interfaces, such as DDR, graphic DDR (GDDR), and low-power DDR (LPDDR), defined by the joint electron device engineering council (JEDEC) standard, but the scope of the inventive concept is not limited thereto.

The memory device 1200 may operate under control by the test device 1100. For example, the memory device 1200 may receive the clock signal CK and the command/address signal CA from the test device 1100 and, in response to the received signals, may transmit the data signal DQ and the data strobe signal DQS to the test device 1100 or receive the data signal DQ and the data strobe signal DQS from the test device 1100.

The PHY 1130 may include a clock generator 1131, a command/address generator 1132, a data receiver 1133, and a data transmitter 1134. The PHY 1130 may receive a DFI signal or DFI field. The PHY 1130 may generate signals with timing and levels conforming to standard protocols, based on the DFI signal, and may transmit the generated signals to the memory device 1200. The PHY 1130 may sample a signal received from the memory device 1200. The PHY 1130 may convert the sampled signal into a DFI signal conforming to the DFI standard. The PHY 1130 may transmit the converted DFI signal to the test control circuit 1120. For example, the PHY 1130 may transmit the read data RDT to the comparator 1123.

The clock generator 1131 may generate the clock signal CK to be provided to the memory device 1200. The generated clock signal CK may be provided to the memory device 1200 through a clock line. For example, the memory device 1200 may operate based on the clock signal CK provided from the test device 1100. The command/address generator 1132 may generate the command/address signal CA to be transmitted to the memory device 1200 under control by the test control circuit 1120. The generated command/address signal CA may be provided to the memory device 1200 through command/address lines.

While the terms “command/address signal CA,” “data signal DQ,” and “data strobe signal DQS” are used for simplicity of the drawing and convenience of description, these terms may respectively refer to a command/address line, data lines, and a data strobe line between the test device 1100 and the memory device 1200, or may refer to signals transmitted through the corresponding lines. Herein, the command/address signal CA may correspond to the command CMD and the address ADDR of FIG. 4A and FIG. 6. The data signal DQ may correspond to the data DT of FIG. 4A and FIG. 6.

The data receiver 1133 may receive the data signal DQ and the data strobe signal DQS from the memory device 1200. The data receiver 1133 may be configured to capture the data signal

DQ at a rising edge or falling edge of the data strobe signal DQS. Received data output from the data receiver 1133 may be provided to the test control circuit 1120. The data transmitter 1134 may output the data signal DQ and the data strobe signal DQS provided from the test control circuit 1120 to the memory device 1200.

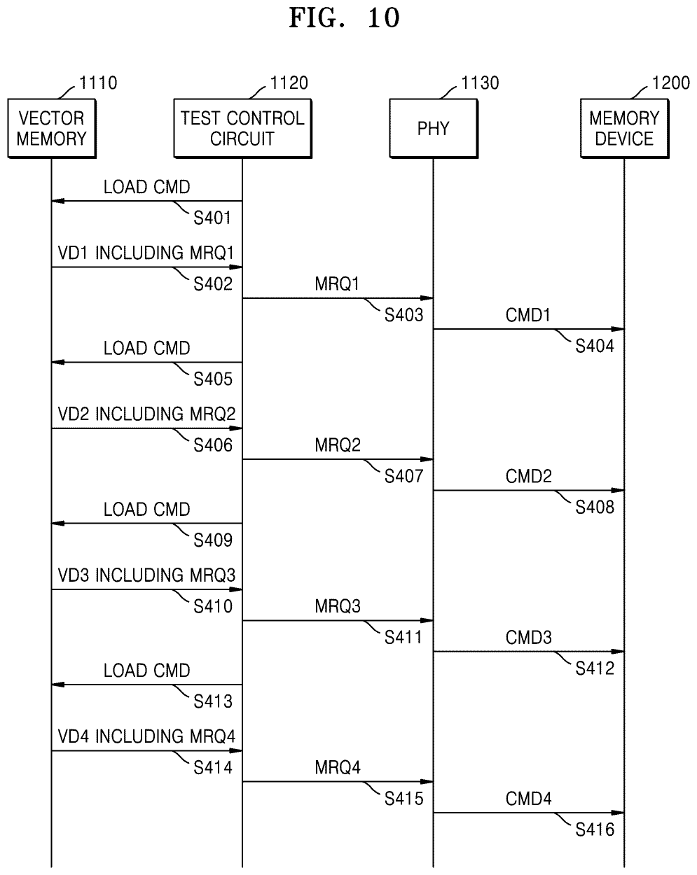

FIG. 10 is a flowchart illustrating an example of an operating method of the test system 1000 according to an embodiment.

Referring to FIGS. 3 and 10, the test device 1100 may perform a test operation on the memory device 1200. The host device 1300 may generate the test data TD. The host device 1300 may generate the test data TD including a plurality of vector data VD. One vector data may correspond to one command. The test device 1100 may perform a test on the memory device 1200 in the order of the vector data VD generated by the host device 1300.

For example, the host device 1300 may generate first to fourth vector data VD1 to VD4. The host device 1300 may sequentially store the first to fourth vector data VD1 to VD4 in the vector memory 1110. For example, the vector memory 1110 may store the first to fourth vector data VD1 to VD4. The first vector data VD1 may include a first memory request MRQ1, the second vector data VD2 may include a second memory request MRQ2, the third vector data VD3 may include a third memory request MRQ3, and the fourth vector data VD4 may include a fourth memory request MRQ4. The vector memory 1110 may sequentially store the first vector data VD1, the second vector data VD2, the third vector data VD3, and the fourth vector data VD4.

In an embodiment, addresses respectively corresponding to the first to fourth vector data VD1 to VD4 may be sequential addresses. For example, a first address corresponding to the first vector data VD1 stored therein, a second address corresponding to the second vector data VD2 stored therein, a third address corresponding to the third vector data VD3 stored therein, and a fourth address corresponding to the fourth vector data VD4 stored therein may be sequential addresses. A sequential address may refer to a set of consecutive addresses. The fact that each of the first to fourth addresses is a sequential address may mean that no other address exists between each pair of the first to fourth addresses. For example, the first to fourth addresses may have sequential address values.

In operation S401, the test control circuit 1120 may transmit a load command to the vector memory 1110. For example, the load command may include the first address. In operation S402, the vector memory 1110 may transmit the first vector data VD1 including the first memory request MRQ1 to the test control circuit 1120.

In operation S403, the test control circuit 1120 may transmit the first memory request MRQ1 to the PHY 1130. The test control circuit 1120 may extract a DFI field from the first vector data VD1. The test control circuit 1120 may transmit the DFI field to the PHY 1130. For example, the test control circuit 1120 may transmit the first memory request MRQ1 in the first vector data VD1 to the PHY 1130.

In operation S404, the PHY 1130 may transmit a first command CMD1 to the memory device 1200. The first command CMD1 may correspond to the first memory request MRQ1. The PHY 1130 may transmit the first command CMD1 to the memory device 1200 based on the first memory request MRQ1.

In operation S405, the test control circuit 1120 may transmit a load command to the vector memory 1110. For example, the load command may include the second address following the first address. In operation S406, the vector memory 1110 may transmit the second vector data VD2 including the second memory request MRQ2 to the test control circuit 1120. In operation S407, the test control circuit 1120 may transmit the second memory request MRQ2 to the PHY 1130. In operation S408, the PHY 1130 may transmit a second command CMD2 to the memory device 1200. The second command CMD2 may correspond to the second memory request MRQ2.

In operation S409, the test control circuit 1120 may transmit a load command to the vector memory 1110. For example, the load command may include the third address following the second address. In operation S410, the vector memory 1110 may transmit the third vector data VD3 including the third memory request MRQ3 to the test control circuit 1120. In operation S411, the test control circuit 1120 may transmit the third memory request MRQ3 to the PHY 1130. In operation S412, the PHY 1130 may transmit a third command CMD3 to the memory device 1200. The third command CMD3 may correspond to the third memory request MRQ3.

In operation S413, the test control circuit 1120 may transmit a load command to the vector memory 1110. For example, the load command may include the fourth address following the third address. In operation S414, the vector memory 1110 may transmit the fourth vector data VD4 including the fourth memory request MRQ4 to the test control circuit 1120. In operation S415, the test control circuit 1120 may transmit the fourth memory request MRQ4 to the PHY 1130. In operation S416, the PHY 1130 may transmit a fourth command CMD4 to the memory device 1200. The fourth command CMD4 may correspond to the fourth memory request MRQ4.

In general, a memory controller may include a bank status register and a command scheduler. The bank status register may store status information on a plurality of banks in a memory device. For example, the status information may indicate whether or not a bank is activated, or whether or not a bank is precharged. The command scheduler may adjust the order in which memory commands and memory addresses are processed, based on the status information on the banks stored in the bank status register.

For example, the memory controller may receive a first request and then receive a second request from a processor. To improve performance, the command scheduler of the memory controller may transmit a second command corresponding to the second request to the memory device and then transmit a first command corresponding to the first request to the memory device.

As such, because the memory controller may change the processing order of commands, it is difficult to transmit commands to the memory device in an order originally set by a user or host device.

In contrast, the test device 1100 according to the inventive concept may not include a command scheduler. The test device 1100 may not adjust the order of commands to be transmitted to the memory device 1200. The test device 1100 may sequentially process the plurality of vector data VD included in the test data TD. The test device 1100 may transmit a command to the memory device 1200 based on the vector data VD. The test device 1100 may transmit commands to the memory device 1200 in an order originally set by a user or the host device 1300. The test device 1100 may not change the order of commands to be transmitted to the memory device 1200.

For example, the test control circuit 1120 may sequentially read the first vector data VD1, the second vector data VD2, the third vector data VD3, and the fourth vector data VD4 from the vector memory 1110. The test control circuit 1120 may sequentially transmit the first memory request MRQ1, the second memory request MRQ2, the third memory request MRQ3, and the fourth memory request MRQ4 to the PHY 1130. The PHY 1130 may sequentially transmit the first command CMD1, the second command CMD2, the third command CMD3, and the fourth command CMD4 to the memory device 1200.

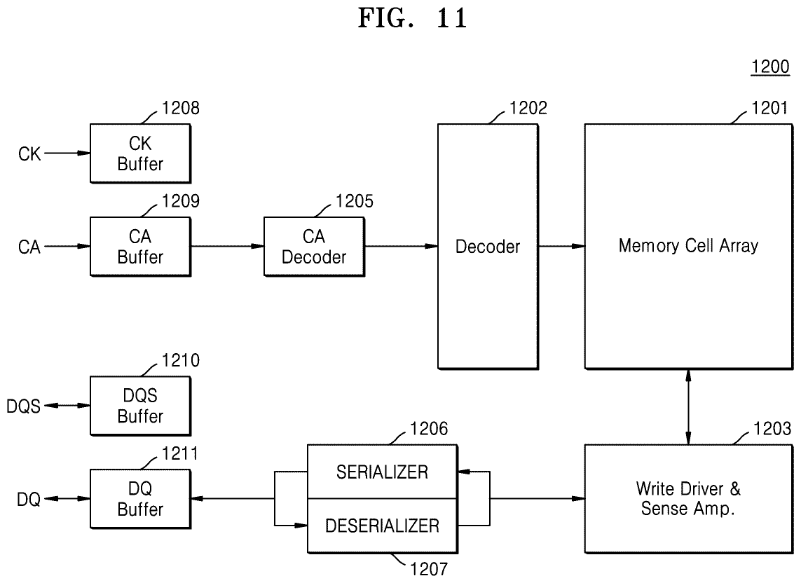

FIG. 11 is a block diagram illustrating the memory device 1200 according to an embodiment.

Referring to FIGS. 1 and 11, the memory device 1200 may include a memory cell array 1201, a decoder 1202, a write driver and sense amplifier 1203, a command/address decoder 1205, a serializer 1206, a deserializer 1207, and buffer circuits, namely, a clock buffer 1208, a command/address buffer 1209, a DQS buffer 1210, and a DQ buffer 1211.

The memory cell array 1201 may include a plurality of memory cells respectively connected to word lines and bit lines (not shown). Each of the plurality of memory cells may be configured to store data or output stored data under control by the decoder 1202 and the write driver and sense amplifier 1203.

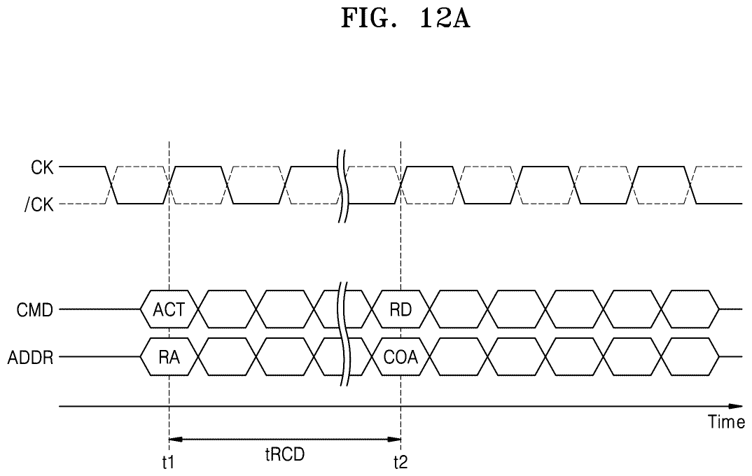

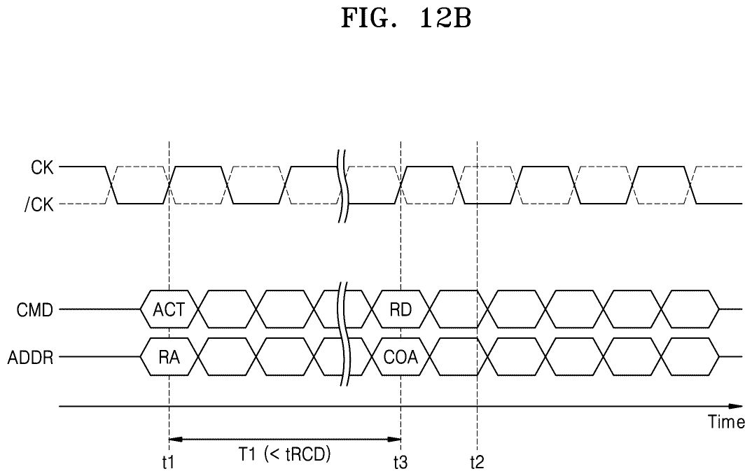

The decoder 1202 may control the plurality of memory cells included in the memory cell array 1201. The decoder 1202 may control the plurality of memory cells based on information (e.g., a decoding result) received from the command/address decoder 1205. For example, the decoder 1202 may decode a row address RA (see FIG. 12A) and activate a word line corresponding to the row address RA. The decoder 1202 may decode a column address COA and activate a column select line corresponding to the column address COA.

The write driver and sense amplifier 1203 may be configured to write data to the plurality of memory cells included in the memory cell array 1201 or output data stored in the plurality of memory cells included in the memory cell array 1201.

The command/address decoder 1205 may decode the command/address signal CA received through the command/address buffer 1209. The command/address decoder 1205 may transmit a decoding result to the decoder 1202.

The serializer 1206 may serialize read data read from the memory cell array 1201. The serialized data may be transmitted to the test device 1100 through the DQ buffer 1211. The deserializer 1207 may deserialize write data received from the test device 1100. The deserialized write data may be stored in memory cells through bit lines.

The clock buffer 1208 may receive the clock signal CK from the test device 1100. The memory device 1200 may operate based on the received clock signal CK. The command/address buffer 1209 may receive the command/address signal CA from the test device 1100 through command/address lines.

The command/address buffer 1209 may transmit the received command/address signal CA to the command/address decoder 1205. The DQS buffer 1210 may receive the data strobe signal DQS from the test device 1100 through a data strobe line. The memory device 1200 may detect input data by sampling, capturing, or deserializing the data by using the data strobe signal DQS. The DQ buffer 1211 may receive input data from the test device 1100 through a plurality of data lines DQ.

FIGS. 12A and 12B are each a timing diagram illustrating an operation of the test device 1100 according to an embodiment.

Referring to FIGS. 7, 11, and 12A, the memory device 1200 may receive an activate command ACT CMD. At least one word line among a plurality of word lines may be selected by the row address RA. The selected word line may be activated by an activate signal ACT. Herein, for convenience of description, the terms of the activate command ACT CMD and the activate signal ACT may be used interchangeably. Also, at least one bit line among a plurality of bit lines may be selected by the column address COA, and a read operation may be performed by a read command RD CMD (or a read command RD).

Memory cells connected to the selected word line may be activated in response to the activate signal ACT, and after a reference time interval (e.g., ACT to internal read or write delay time (tRCD) has elapsed, the column address COA and the read command RD CMD may be input to the decoder 1202. While the above-described embodiments have been described based on a read operation of the memory device 1200, the scope of the inventive concept is not limited thereto. For example, even in a write operation of the memory device 1200, a write command may be received after the reference time interval (e.g., tRCD) has elapsed from a time point when the activate command ACT CMD is received.

For example, the test device 1100 may transmit the activate command ACT CMD and the row address RA at a first time point t1. The test device 1100 may transmit the read command RD CMD and the column address COA at a second time point t2 when the reference time interval (e.g., tRCD) has elapsed from the first time point t1.

At the first time point t1, the memory device 1200 may receive the activate command ACT CMD and the row address RA. In the memory device 1200, a word line may be selected by the row address RA transmitted from the decoder 1202 to the memory cell array 1201, in response to the activate command ACT CMD. Also, the activate signal ACT may be transmitted to the selected word line.

Thereafter, at the second time point t2 when the reference time interval (e.g., tRCD) has elapsed from the first time point t1, the memory device 1200 may receive the read command RD CMD and the column address COA. The column address COA and the read command RD CMD may be transmitted to the decoder 1202.

Referring to FIGS. 7, 11, and 12B, the test device 1100 may transmit the activate command ACT CMD and the row address RA at the first time point t1. The the test device 1100 may transmit the read command RD CMD and the column address COA at a third time point t3 when a first time interval T1 has elapsed from the first time point t1. The first time interval T1 may be less than the reference time interval (e.g., tRCD). For example, the PHY 1130 may transmit the activate command ACT CMD and the read command RD CMD to the memory device 1200 after a time less than the reference time interval (e.g., tRCD).

To test the memory device 1200, the test device 1100 may transmit a command different from an established protocol. The test device 1100 may inject an error to check whether or not the memory device 1200 handles the error correctly. That is, the test device 1100 may test the memory device 1200 by performing an error injection operation. The test device 1100 may check error handling of the memory device 1200 through the error injection operation.

In an embodiment, to inject an error, the test device 1100 may transmit a command or output a signal at a time different from a time determined by a standard specification. For example, the test device 1100 may transmit the read command RD CMD after the first time interval T1, which is less than the reference time interval (e.g., tRCD), has elapsed from a time point (i.e., t1) when the activate command ACT CMD is transmitted. However, the scope of the inventive concept is not limited thereto, and various reference time intervals determined by standards may be adjusted.

In an embodiment, to inject an error, the test device 1100 may transmit a command or output a signal with a value different from a value determined by a standard specification. The test device 1100 may transmit an invalid command violating a standard specification to the memory device 1200. For example, the test device 1100 may set and output a signal value different from those in a command truth table determined by a standard specification. The test device 1100 may transmit all (or most of) commands implemented in the ATE to the memory device 1200 and test the commands.

The test device 1100 may adjust a time interval (the number of toggling times of a clock signal) between commands by using the operand OPERAND included in the vector data VD. The test device 1100 may transmit commands not conforming to standard specifications to the memory device 1200. For example, the test device 1100 may adjust a time interval between commands by decreasing or increasing a value of the operand OPERAND of the vector data VD.

For example, to inject an error, the test device 1100 may transmit the activate command ACT CMD at the first time point t1, and may transmit the read command RD CMD at the third time point t3 after the first time interval T1. The test device 1100 may decrease a time interval (or the number of toggling times of a clock signal) between the activate command ACT CMD and the read command RD CMD by decreasing the value of the operand OPERAND of the vector data VD.

As described above, a test device including a memory controller may have difficulty in performing an error injection operation. In contrast, the test device 1100 according to an embodiment may perform a test operation based on the vector data VD. The vector data VD may include DFI signals without changes. The test control circuit 1120 may transmit the DFI signals to the PHY 1130 without changes. For example, to perform an error injection operation, the test device 1100 may perform a test operation on the memory device 1200 based on test data generated by the host device 1300. The test device 1100 may perform the same function as ATE.

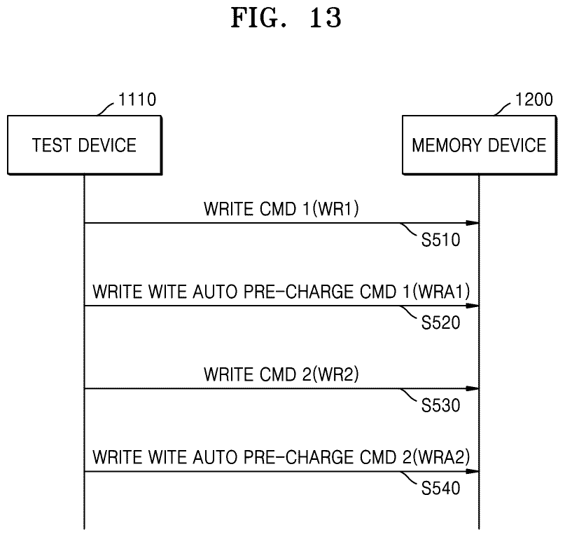

FIG. 13 is a flowchart illustrating an example of an operating method of the test system 1000 according to an embodiment.

The memory device 1200 may enter an active state from an idle state in response to the activate command ACT. The active state may refer to a state in which a selected word line is activated. The memory device 1200 in the active state, a writing state, or a reading state may enter the writing state or the reading state in response to a write command WR or a read command RD, and may enter the active state after performing a write operation (i.e., an operation of writing data into memory cells) or a read operation (i.e., an operation of outputting data).

The memory device 1200 in the active state, the writing state, or the reading state may enter the writing state or the reading state in response to a write with auto precharge command WRA or a read with auto precharge command RDA, and may enter a precharging state after performing a write operation or a read operation. The write with auto precharge command WRA or the read with auto precharge command RDA may be a command for performing a precharge operation after completing a write operation or a read operation without a separate precharge command PRE.

The memory device 1200 in the active state, writing state, or reading state may enter the precharging state in response to the precharge command PRE. The memory device 1200 in the precharging state may enter the idle state after completing a precharging operation.

Referring to FIGS. 1 and 13, in operation S510, the test device 1100 may transmit a first write command WR1 to the memory device 1200. In operation S520, the test device 1100 may transmit a first write with auto precharge command WRA1 to the memory device 1200. In operation S530, the test device 1100 may transmit a second write command WR2 to the memory device 1200. In operation S540, the test device 1100 may transmit a second write with auto precharge command WRA2 to the memory device 1200. For example, the PHY 1130 may sequentially transmit the first write command WR1, the first write with auto precharge command WRA1, the second write command WR2, and the second write with auto precharge command WRA2 to the memory device 1200.

While the above-described embodiments have been described based on a write operation of the memory device 1200, the scope of the inventive concept is not limited thereto. For example, the test device 1100 may perform a test on the memory device 1200 by using a combination of the read command RD and the read with auto precharge command RDA.

In general, a memory controller may not transmit the write command WR and the write with auto precharge command WRA to the memory device 1200 in combination. That is, the memory controller may only transmit a plurality of write commands WR. Alternatively, the memory controller may only transmit a plurality of write with auto precharge commands WRA. Also, the memory controller may not transmit the read command RD and the read with auto precharge command RDA to the memory device 1200 in combination. That is, the memory controller may only transmit a plurality of read commands RD. Alternatively, the memory controller may only transmit a plurality of read with auto precharge commands RDA. As such, a test device including the memory controller may not replace an ATE device due to limitations of the memory controller. The test device including the memory controller may not perform various tests on the memory device 1200.

In contrast, the test device 1100 according to an embodiment may perform a test in which the write command WR and the write with auto precharge command WRA are combined. For example, the test device 1100 may transmit the write command WR and the write with auto precharge command WRA to the memory device 1200 in combination. The test device 1100 may perform a test operation based on the vector data VD, and may transmit the DFI signals included in the vector data VD to the PHY 1130 without conversion. The test device 1100 may perform tests of various sequences or patterns. Accordingly, the test device 1100 may have an increased test coverage.

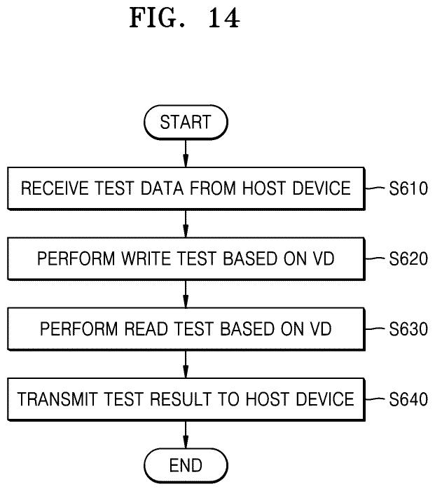

FIG. 14 is a flowchart illustrating an example of an operating method of the test system 1000 according to an embodiment.

In operation S610, the test device 1100 may receive test data from the host device 1300. For example, the host device 1300 may generate test data including a plurality of vector data VD. The host device 1300 may store the test data in the vector memory 1110 of the test device 1100.

In operation S620, the test device 1100 may perform a write test based on the plurality of vector data VD. The test control circuit 1120 may transmit a memory request (e.g., a write request), a memory address, and memory data included in the vector data VD to the PHY 1130. The PHY 1130 may transmit a write command and an address to the memory device 1200 through a command/address line. The PHY 1130 may transmit data to the memory device 1200 through a plurality of data lines. The test control circuit 1120 may write data to the memory device 1200.

In operation S630, the test device 1100 may perform a read test based on the plurality of vector data VD. The test control circuit 1120 may transmit a memory request (e.g., a read request) and a memory address included in the vector data VD to the PHY 1130. The PHY 1130 may transmit a read command and an address to the memory device 1200 through a command/address line. The PHY 1130 may receive data from the memory device 1200 through a plurality of data lines.

The test control circuit 1120 may detect a defect in the memory device 1200 by comparing read data received from the memory device 1200 with expected data included in the vector data VD. The test control circuit 1120 may store a test result in the buffer memory 1124. The test result may include information about defects occurring in a write or read operation.

In operation S640, the test device 1100 may transmit the test result to the host device 1300. For example, to confirm and analyze defects in the memory device 1200 based on the test result, the host device 1300 may transmit a test result request to the test device 1100. The test device 1100 may transmit the test result stored in the buffer memory 1124 to the host device 1300.

In an embodiment, if no defect occurs in the memory device 1200, the test device 1100 may not generate a test result. When there is no test result stored in the buffer memory 1124, the test device 1100 may not transmit a test result in response to the test result request received from the host device 1300. Alternatively, the test device 1100 may transmit dummy data to the host device 1300. For example, the dummy data may be a signal having a logic level ‘0’.

In another embodiment, if there is no DUT, the test device 1100 may not generate and not transmit a test result in response to the test result request received from the host device 1300.

In an embodiment, the host device 1300 may determine success or failure of a test operation based on the presence or absence of a test result. For example, when there is no test result in the buffer memory 1124, the host device 1300 may determine the test operation to be a success (i.e., the memory device 1200 has no defect). When there is a test result in the buffer memory 1124, the host device 1300 may determine the test operation to be a failure (i.e., the memory device 1200 has a defect).

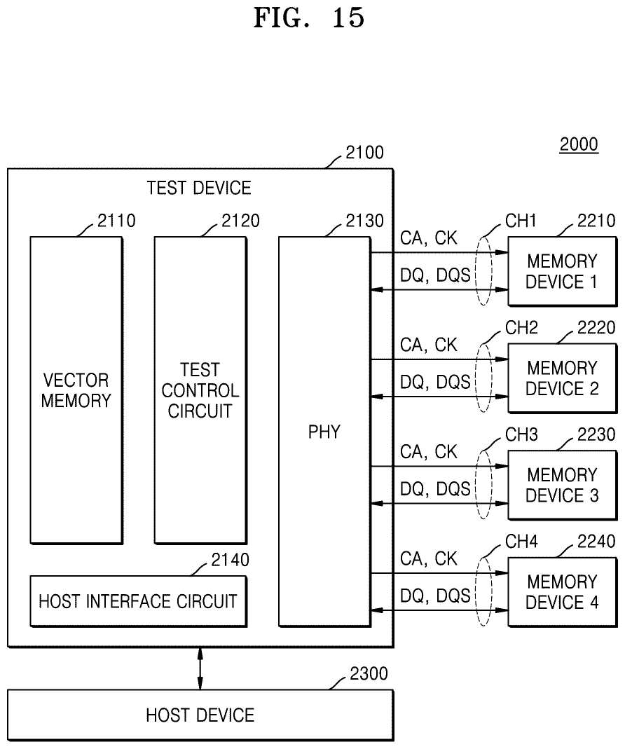

FIG. 15 is a block diagram illustrating a test system 2000 according to an embodiment.

Referring to FIG. 15, the test system 2000 may include a test device 2100, a plurality of memory devices, for example, first to fourth memory devices 2210, 2220, 2230, and 2240, and a host device 2300. The test device 2100 may include a vector memory 2110, a test control circuit 2120, a PHY 2130, and a host interface circuit 2140. As described with reference to FIGS. 1 to 3, 4A, 4B, 5 to 11, 12A, 12B, 13, and 14, the test device 2100 may perform a test operation.

The test device 2100 may perform test operations on the first to fourth memory devices 2210, 2220, 2230, and 2240. For example, the test device 2100 may simultaneously test the first to fourth memory devices 2210, 2220, 2230, and 2240. However, the scope of the inventive concept is not limited thereto, and the number of memory devices may increase or decrease depending on implementation.

The test device 2100 may communicate with the first to fourth memory devices 2210, 2220, 2230, and 2240 through a plurality of channels, for example, first to fourth channels CHI to CH4. For example, the test device 2100 may communicate with the first memory device 2210 through the first channel CH1, may communicate with the second memory device 2220 through the second channel CH2, may communicate with the third memory device 2230 through the third channel CH3, and may communicate with the fourth memory device 2240 through the fourth channel CH4. In example embodiments, command/address signals CA, clock signals CK, data signals DQ, and data strobe signals DQS may be provided to each of the first to fourth channels CHI to CH4.

In example embodiments, the command/address signals CA may be provided to the first to fourth memory devices 2210, 2220, 2230, and 2240 in common, and a clock signal CK may be provided to the first to fourth memory devices 2210, 2220, 2230, and 2240 in common.

In example embodiments, first command/address signals CA may be provided to the first and second memory devices 2210 and 2220 in common, and a first clock signal CK may be provided to the first and second memory devices 2210 and 2220 in common. Second command/address signals CA may be provided to the third and fourth memory devices 2230 and 2240 in common, and a second clock signal CK may be provided to the third and fourth memory devices 2230 and 2240 in common.

For example, the test device 2100 may test the first memory device 2210 through the first channel CH1. The test device 2100 may test the second memory device 2220 through the second channel CH2. The test device 2100 may test the third memory device 2230 through the third channel CH3. The test device 2100 may test the fourth memory device 2240 through the fourth channel CH4.

In general, an ATE device may have a per-pin architecture. Accordingly, the ATE device may require a plurality of ASICs to generate signals for one DUT. In contrast, the test device 1100 according to an embodiment may simultaneously perform test operations on a plurality of memory devices or DUTs. Accordingly, when implementing a test system, costs and space for manufacturing equipment may be reduced.

While the inventive concept has been particularly shown and described with reference to embodiments thereof, it will be understood that various changes in form and details may be made therein without departing from the spirit and scope of the present invention as set forth in the following claims.

What is claimed is:

1. A test device comprising:
a vector memory configured to store a plurality of vector data;
a test control circuit configured to test an external memory device by:
receiving a first vector data among the plurality of vector data,
transmitting a first memory request, a memory address, and memory data included in the first vector data, and
comparing read data from the external memory device with expected data; and
a physical layer configured to:
communicate with the external memory device through data lines and a command/address line,
output a first command corresponding to the first memory request and an address corresponding to the memory address through the command/address line,
output write data corresponding to the memory data through the data lines,
receive the first memory request, the memory address, and the memory data from the test control circuit, and
receive the read data from the external memory device through the data lines,
wherein the first vector data includes the first memory request, the memory address, the memory data, and the expected data.

2. The test device of claim 1, wherein the physical layer includes a double data rate (DDR) PHY intellectual property (IP) block.

3. The test device of claim 1, wherein the test control circuit and the physical layer communicate with each other according to a double data rate (DDR) PHY interface (DFI).

4. The test device of claim 1, wherein the first memory request, the memory address, and the memory data include signals defined by a double data rate (DDR) PHY interface (DFI) standard.

5. The test device of claim 1, wherein the test control circuit comprises:
a sequencer configured to load the first vector data from the vector memory and transmit the first vector data;
a command decoder configured to receive the first vector data from the sequencer, transmit the first memory request, the memory address, and the memory data in the first vector data to the physical layer, and transmit a comparison enable signal and the expected data in the first vector data;
a comparator configured to receive the comparison enable signal and the expected data from the command decoder, receive the read data from the physical layer, generate a fail entry based on a comparison result between the read data and the expected data, and transmit the fail entry; and
a buffer memory configured to receive the fail entry from the comparator.

6. The test device of claim 5, wherein the sequencer is further configured to:
receive a start address from an external host device, and
read the first vector data from the vector memory in response to the start address, and
wherein the buffer memory is further configured to transmit a test result including a plurality of fail entries to the external host device in response to a test result request command received from the external host device.

7. The test device of claim 5, wherein:
the first vector data includes a command field, a double data rate (DDR) PHY interface (DFI) field, and a comparison field,
the command field includes an operation code and an operand,
the DFI field includes the first memory request, the memory address, and the memory data, and the comparison field includes the comparison enable signal and the expected data.

8. The test device of claim 7, wherein the command decoder comprises:
a first-in-first-out (FIFO) configured to store the first vector data received from the sequencer, transmit the command field in response to a FIFO enable signal, transmit the DFI field to the physical layer, and transmit the comparison field to the comparator;
an operation code decoder configured to receive the command field from the FIFO, perform a decoding operation based on the operation code, output a halt signal to the sequencer in response to the operation code indicating a halt code, and transmit the operand in response to the operation code indicating a loop code; and
a loop counter configured to receive the operand from the operation code decoder, set the operand as a count value, and output the FIFO enable signal after the number of clock cycles corresponding to the count value.

9. The test device of claim 1, wherein:
the plurality of vector data includes second to fourth vector data,
the second vector data includes a second memory request,
the third vector data includes a third memory request,
the fourth vector data includes a fourth memory request, and
the test control circuit is further configured to sequentially read the first vector data, the second vector data, the third vector data, and the fourth vector data from the vector memory, and sequentially transmit the first memory request, the second memory request, the third memory request, and the fourth memory request to the physical layer.

10. The test device of claim 9, wherein the physical layer is further configured to sequentially transmit, to the external memory device, the first command, a second command corresponding to the second memory request, a third command corresponding to the third memory request, and a fourth command corresponding to the fourth memory request.

11. The test device of claim 1, wherein the physical layer is further configured to sequentially transmit a first write command, a first write with auto precharge command, a second write command, and a second write with auto precharge command to the external memory device.

12. The test device of claim 1, wherein the physical layer is further configured to transmit an activate command and transmit a read command after a time interval less than a reference time interval.

13. An operating method of a test device including a physical layer, a vector memory, and a test control circuit, the operating method comprising:
receiving, by the test control circuit, vector data stored in the vector memory;
transmitting, by the test control circuit, a memory request, a memory address, and memory data included in the vector data to the physical layer;
transmitting, by the physical layer, a command corresponding to the memory request and an address corresponding to the memory address, to an external memory device through a command/address line; and
transmitting, by the physical layer, data corresponding to the memory data to the external memory device through data lines.

14. The operating method of claim 13, further comprising:
receiving, by the test control circuit, a test start request and a start address from an external host device;
transmitting, by the test control circuit, a load command to the vector memory to load the vector data from the vector memory, in response to the test start request;
receiving, by the vector memory, test data comprising a plurality of vector data from the external host device; and
storing, by the vector memory, the test data.

15. The operating method of claim 13, further comprising:
receiving, by the physical layer, data from the external memory device;
transmitting, by the physical layer, the data as read data to the test control circuit;
comparing, by the test control circuit, the read data with expected data included in the vector data; and
when the read data is different from the expected data, generating and storing a fail entry.

16. The operating method of claim 15, further comprising:
receiving, by the test control circuit, a test result request from an external host device; and
transmitting, by the test control circuit, a test result including a plurality of fail entries to the external host device, in response to the test result request,
wherein the test result includes the memory address, the read data, and the expected data.

17. The operating method of claim 13, further comprising:
determining, by the test control circuit, whether or not an operation code included in the vector data is a halt code;
halting, by the test control circuit, a loading operation of loading the vector data from the vector memory when the operation code is a halt code; and
transmitting, by the test control circuit, a test end signal to an external host device when the loading operation is halted.

18. A test system comprising:
a test device; and
a memory device,
wherein the test device comprises:
a vector memory configured to store a plurality of vector data;
a test control circuit configured to test the memory device by:
receiving a first vector data among the plurality of vector data,
transmitting a memory request, a memory address, and memory data included in the first vector data, and
comparing read data from the memory device with expected data included in the first vector data to generate and store a test result; and
a physical layer configured to:
communicate with the memory device through data lines and a command/address line,
output a command corresponding to the memory request and an address corresponding to the memory address, through the command/address line, and
output write data corresponding to the memory data through the data lines, and receive the read data through the data lines,
wherein the physical layer includes an intellectual property (IP) block, and
wherein the memory request, the memory address, and the memory data comprise signals defined by a double data rate (DDR) PHY interface (DFI) standard.

19. The test system of claim 18, wherein the test control circuit comprises:
a sequencer configured to load the first vector data from the vector memory and transmit the first vector data;
a command decoder configured to receive the first vector data from the sequencer, transmit the memory request, the memory address, and the memory data in the first vector data to the physical layer, and transmit a comparison enable signal and the expected data in the first vector data;
a comparator configured to receive the comparison enable signal and the expected data from the command decoder, receive the read data from the physical layer, and transmit a fail entry based on a comparison result between the read data and the expected data; and
a buffer memory configured to receive the fail entry from the comparator.

20. The test system of claim 19, wherein:
the first vector data includes a command field, a DFI field, and a comparison field,
the command field includes an operation code and an operand,
the DFI field includes the memory request, the memory address, and the memory data,
the comparison field includes the comparison enable signal and the expected data, and
the command decoder comprises:
a first-in-first-out (FIFO) configured to store the first vector data received from the sequencer, transmit the command field in response to a FIFO enable signal, transmit the DFI field to the physical layer, and transmit the comparison field to the comparator;
an operation code decoder configured to receive the command field from the FIFO, perform a decoding operation based on the operation code, output a halt signal to the sequencer in response to the operation code indicating a halt code, and transmit the operand in response to the operation code indicating a loop code; and
a loop counter configured to receive the operand from the operation code decoder, set the operand as a count value, and output the FIFO enable signal after the number of clock cycles corresponding to the count value.
